(19) United States
(12) Patent Application Publication
(10) Pub. No.: US 2023/0365399 A1
(43) Pub. Date: Nov. 16, 2023

(54) PLUG FOR MEMS CAVITY

(71) Applicant: Murata Manufacturing Co., Ltd., Nagaokakyo-shi (JP)

(72) Inventor: Petteri KILPINEN, Espoo (FI)

(21) Appl. No.: 18/316,410

(22) Filed: May 12, 2023

(30) Foreign Application Priority Data
May 13, 2022 (FI) 20225423

(51) Int. Cl. B81B 7/00; B81C 1/00

(52) U.S. Cl. CPC B81B 7/0041; B81C 1/00293; B81B 2201/0235; B81B 2201/0242; B81C 2203/0145

(57) ABSTRACT

A microelectromechanical is provided that includes a support layer, a device layer and a cap layer, a first cavity and a second cavity. The first cavity and the second cavity are delimited by the support layer, the device layer and the cap layer. Moreover, the cap layer includes a through-hole that extends from the top surface of the cap layer to the first cavity. The microelectromechanical component includes a plug inside the through-hole and that seals the first cavity.

### CROSS REFERENCE TO RELATED APPLICATIONS

This application claims priority to Finnish Patent Application No. 20225423, filed May 13, 2022, the contents of which are hereby incorporated by reference in its entirety.

### TECHNICAL FIELD

The present disclosure relates to microelectromechanical (MEMS) components, and more particularly to MEMS components comprising two MEMS elements enclosed in gas-filled cavities. The present disclosure further concerns MEMS components where the two MEMS elements should be surrounded by different gases.

### BACKGROUND

Microelectromechanical elements can be used to measure acceleration and rotation (e.g., angular velocity). It is often convenient to include multiple MEMS elements in the same component package. This can be done by inserting multiple MEMS dies in the same package, for example, one die for measuring acceleration in the device plane, one for measuring acceleration perpendicular to the device plane, one die for measuring angular velocity about axes which lie in the device plane and one for measuring angular velocity about an axis perpendicular to the device plane. However, manufacturing each die separately is costly and quite a lot of surface area is needed in the component when each individual MEMS element has its own die. Significant cost and area savings can be obtained if several MEMS elements can be built on the same die. Using the same device layer for multiple MEMS elements also has the additional benefit that it becomes easier to secure their orientation with respect to each other, for example, in terms of horizontal direction and possibly vertical tilt.

In general, MEMS elements contain moving device structures. The acceleration and/or rotation which the component undergoes can be detected by measuring how the movement of such device structures changes. In order to function properly, the device structures must be enclosed in cavities where there is room for the desired movement and where the surrounding gas atmosphere is suitable. A common challenge in building multiple elements on the same die is that the gas atmosphere which is ideal for one element may not be ideal for the other element which should be included on the same die. For example, it may be beneficial for an accelerometer to be surrounded by relatively high gas pressure (for example, one atmosphere) because gas damping can prevent excessive movement due to external shocks, which could otherwise damage the element. A gyroscope, on the other hand, will function properly and accurately if the gas pressure is much lower, for example, close to vacuum. The gas itself may sometimes also need to be different in the two cavities.

U.S. Patent Publication No. 2017/0050841 presents a MEMS component where two elements on the same die are enclosed in cavities with different gas pressures. A through-hole in a capping structure allows a second cavity to be filled with a different gas pressure after the cap has sealed a first cavity. An additional covering structure is then bonded on top of the capping structure to cover the through-hole and seal the second cavity. However, the reliability of this sealing is not optimal.

### SUMMARY OF THE INVENTION

Accordingly, it is an object of the present disclosure to provide a method and an apparatus for alleviating the above disadvantages.

Thus, in an exemplary aspect, a microelectromechanical component is disclosed that includes a support layer; a device layer on the support layer; and a cap layer having a top surface and that is on the device layer opposite to the support layer. In this aspect, the support layer, the device layer and the cap layer define a first cavity and a second cavity, the device layer includes a first microelectromechanical device structure in the first cavity and a second microelectromechanical device structure in the second cavity, the cap layer comprises a through-hole that extends from the top surface of the cap layer to the first cavity, and a plug is disposed inside the through-hole to seal the first cavity.

In another exemplary aspect, the cap layer comprises one or more silicon regions, and the through-hole is in one of the one or more silicon regions.

In another exemplary aspect, the cap layer comprises two or more silicon regions and one or more insulating regions that separate the two or more silicon regions electrically from each other.

In another exemplary aspect, the cap layer comprises two or more silicon regions and one or more insulating regions that separate the two or more silicon regions electrically from each other, and the through-hole is in one of the insulating regions.

In another exemplary aspect, the microelectromechanical component further includes at least one internal wall that divides the first cavity into two or more sub-cavities. In this aspect, two or more through-holes can be provided that respective extend into each of the two or more sub-cavities, respectively.

In another exemplary aspect, the width of the through-hole decreases as a function of depth.

In yet another exemplary aspect, a microelectromechanical component is provided that includes a support layer that includes a first cavity and a second cavity disposed therein; a device layer on the support layer and including a first microelectromechanical device structure in the first cavity and a second microelectromechanical device structure in the second cavity; a cap layer on the device layer opposite to the support layer and including a through-hole that extends from an outer surface of the cap layer to the first cavity; and a plug in the through-hole to seal the first cavity.

In yet another exemplary aspect, a method is provided for manufacturing a microelectromechanical component that includes a support layer, a device layer and a cap layer. In this aspect, the method includes forming recessed regions in at least one of the support layer, the device layer and in the cap layer to define for delimiting a first cavity and a second cavity; forming a through-hole through the cap layer; attaching the cap layer to the device layer in a surrounding first gas atmosphere so that the through-hole overlies the first cavity; changing the surrounding first gas atmosphere to a surrounding second gas atmosphere that is different than the surrounding first gas atmosphere; and depositing a layer of plug material on the top surface of the cap layer at least over the through-hole until a plug that seals the through-hole is formed inside the through-hole.

The exemplary aspects of the present disclosure are based on the idea of sealing a cavity with a plug that fills a through-hole in a cap layer. An advantage of this arrangement is that the sealing is highly reliable.

### BRIEF DESCRIPTION OF THE DRAWINGS

In the following the disclosure will be described in greater detail by means of preferred embodiments with reference to the accompanying drawings, in which

FIGS. 1a-1f illustrate microelectromechanical components with plugs.

FIGS. 2a-2b illustrate components where the cap layer also comprises an insulating material.

FIG. 3 illustrates a component where the first cavity comprises an internal wall.

FIGS. 4a-4g illustrate a method for manufacturing a component.

### DETAILED DESCRIPTION

This disclosure describes a microelectromechanical component comprising a support layer, a device layer and a cap layer. The cap layer has a top surface. The cap layer is on top of the device layer that is on top of the support layer. The component further comprises a first cavity and a second cavity. Both the first cavity and the second cavity are delimited by the support layer, the device layer and the cap layer. The device layer comprises a first microelectromechanical device structure in the first cavity and a second microelectromechanical device structure in the second cavity. The cap layer comprises a through-hole that extends from the top surface of the cap layer to the first cavity. The microelectromechanical component comprises a plug inside the through-hole. The plug seals the first cavity.

In an exemplary aspect, the support layer may be a support wafer or handle wafer. It may be made of silicon, but other materials can also be used in other aspects. The device layer may be a device wafer which has been bonded onto the support layer, or it may be a layer which has been deposited onto the support layer. The device layer may be a layer of silicon. The device layer and the support layer may for example be parts of a silicon-on-insulator (SOI) substrate where MEMS elements can be formed by patterning the top silicon layer (e.g., the device layer).

The plane of the device layer may be called the device plane and it may be illustrated as an xy-plane. Any direction or plane that is parallel to the device plane may be called horizontal or a horizontal plane. The direction that is perpendicular to the device plane may be illustrated with a z-axis and be called the vertical direction. Expressions such as “top”, “bottom”, “above”, “below”, “up” and “down” refer in this disclosure to differences in the vertical z-coordinate. These expressions do not imply anything about how the device should be oriented with respect to the Earth's gravitational field when the component is in use or when it is being manufactured.

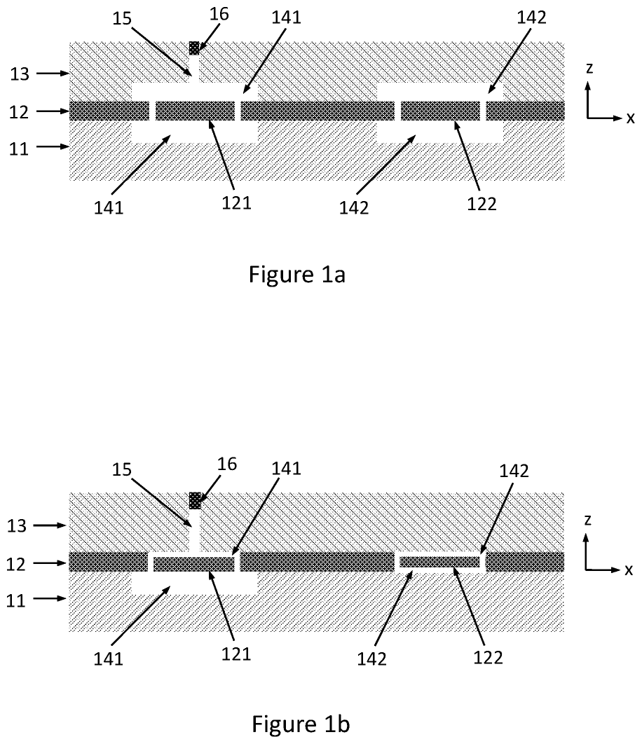

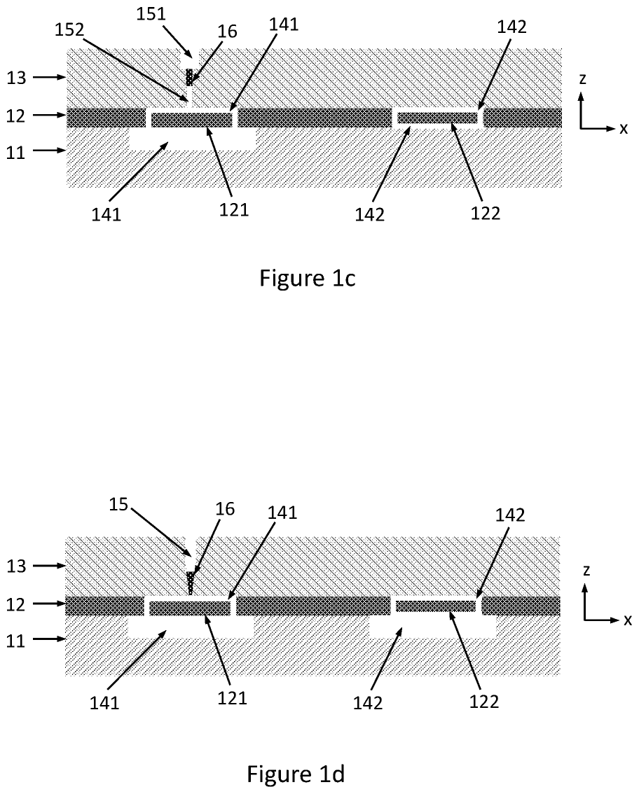

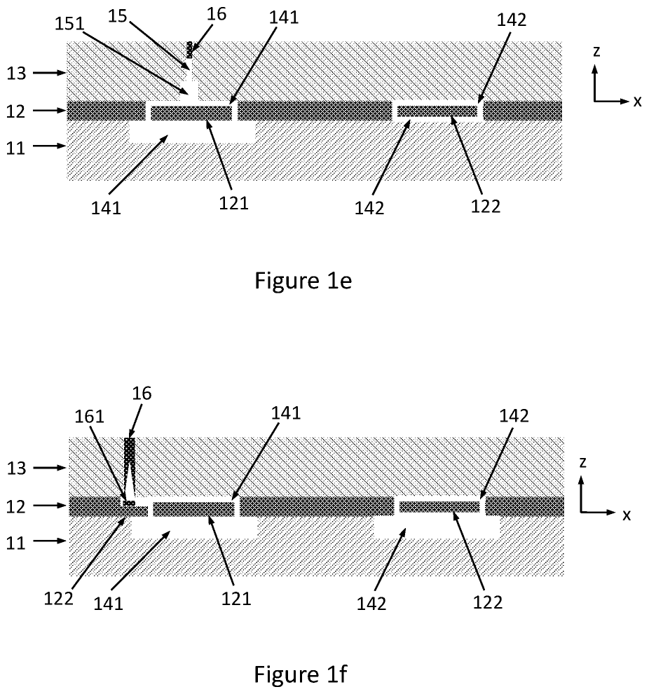

FIG. 1a illustrates a microelectromechanical component with a support layer 11, a device layer 12 and a cap layer 13. The component also comprises a first cavity 141 and a second cavity 142. The cap layer 13 covers both cavities 141 and 142. First and second microelectromechanical device structures 121 and 122 have been formed in the device layer so that these structures are located within the first and second cavities. The device structures are shown as disconnected parts in FIG. 1a to illustrate that they contain mobile parts which can move in relation to the fixed parts of the device layer. In practice and operation, these mobile parts are suspended from the fixed parts of the device layer by thin flexible structures which may be called suspenders. The suspenders allow the mobile parts to move in relation to the fixed parts, for example in oscillating motion driven by force transducers and/or by external forces.

According to exemplary embodiments presented in this disclosure, the cap layer may cover both the first cavity and the second cavity.

In the exemplary embodiments in this disclosure, the thickness of the device layer in the z-direction may, for example, be greater than 10 μm, greater than 20 μm, greater than 40 μm or greater than 50 μm. Moreover, the thickness of the cap layer may be greater than 50 μm, greater than 100 μm or greater than 200 μm, for example.

The first cavity 141 and the second cavity 142 must be sufficiently large to allow the mobile parts of the first and second microelectromechanical device structure to undergo the desired movement (e.g., vibration) without coming into contact with the sidewalls, top or bottom of the cavity. The bottom of the cavities is formed by the support layer and the top is formed by the cap layer. The sidewalls may be formed in the support layer, the device layer and the cap layer together, as FIG. 1b illustrates.

The cavities 141 and 142 may be formed by etching recessed areas in the support layer and/or the device layer and/or the cap layer before the three layers are joined to each other. In the device illustrated in FIG. 1a, the cavities have been formed in both the support layer 11 and in the cap layer 13. FIG. 1b illustrates an alternative option where, in the first cavity 141, the support layer 11 has been recessed to create room between the bottom of the first cavity 141 and the first device structure 121. The top side of the first device structure 121 has also been recessed in the vertical direction to create space between the top of the first cavity (which is in this case just the bottom surface of the cap layer 13 which overlies the cavity) and the first device structure 121. The second cavity 142, on the other hand, has been created only by recessing the device layer both from its top side and from its bottom side. Moreover, the bottom of the second cavity 142 is formed by the top surface of the support layer 11 and the top of the second cavity is formed by the bottom surface of the cap layer 13. The second device structure 122 does not have much room for vertical movement in the second cavity 142. The mobile parts in this device structure may be intended to undergo only horizontal movement. Their suspenders may be horizontally flexible, but stiff in the vertical direction. In all of these cases, the cavities are delimited by the support layer, the device layer and the cap layer. The cavity options illustrated in FIGS. 1a and 1b are applicable in all embodiments presented in this disclosure.

In FIGS. 1a-1b the cap layer 13 comprises at least one through-hole 15 that extends in the vertical direction through the cap layer 13 to the first cavity 141. The through-hole may be a fully vertical through-hole as FIGS. 1a-1b illustrate, but it could alternatively have a more complicated meandering shape. The component also comprises a plug 16 inside the through-hole 15. The plug 16 fills the through-hole 15 so that the first cavity 141 is hermetically sealed from the surrounding atmosphere.

Although only one through-hole is illustrated in the embodiments, the component may comprise one, two, three, four or more through-holes which all extend to the first cavity or sub-cavity according to alternative exemplary aspects. Each through-hole is in this case sealed with its own plug. Many considerations could influence this choice. Using just one through-hole requires very little surface area. But after the second cavity has been sealed by the cap layer and the gas atmosphere which surrounds the device is changed to the one which should fill the first cavity, the gas transfer in and out of the first cavity may be slow if there is only one through-hole. The transfer rate may then be increased by using more than one through-hole. On the other hand, using more than one through-hole may increase the chance that one of the plugs has a structural flaw and begins to leak. Finally, there may also be a risk that some through-holes are incompletely etched, which would make gas transfer impossible between the first cavity and the surroundings. Using more than one through-holes increases the chance that at least some through-holes will be etched completely through the cap layer.

The through-hole is a channel through the cap layer which allows gas to enter and exit the first cavity after the cap layer has been attached to the device layer. The through-hole may alternatively be called a feedthrough. The through-hole may have an approximately circular shape in the xy-plane, so that a horizontal through-hole diameter can be defined. However, the through-hole could also have one longer dimension and one shorter dimension in the xy-plane, so that it forms a trench which is for example narrow in the x-direction but much wider in the y-direction (which is perpendicular to the x- and z-directions illustrated in the figures). In this case, the width of the trench (in the narrower x-dimension) is the key dimensional variable.

According to the exemplary aspect, the plug 16 may be located in the top part of the through-hole as FIGS. 1a and 1b illustrate. The horizontal diameter or width of the through-hole may in this case be substantially the same at all z-coordinates. Alternatively, the through-hole may comprise a wider part 151 at the top and a narrower part 152 at the bottom, and the plug 16 may be located in this narrower part as FIG. 1c illustrates.

In any embodiment of this disclosure, the horizontal diameter or width of the part of the through-hole where the plug is located may for example in any of the ranges 0.5-3 μm, 1-3 μm, 1 μm-5 μm, 1 μm-8 μm, 3 μm-5 μm, 5 μm-8 μm or 1 μm-10 μm or 5 μm-10 μm. The width could alternatively be made smaller than 0.5 μm, but the risk of incomplete etching may then become unacceptably high as would be appreciated to one skilled in the art.

The width of the through-hole may decrease as a function of depth, as FIGS. 1c and 1d illustrate. In FIG. 1d the through-hole has the shape of a carrot (i.e., tapering inwards), becoming gradually narrower closer to the first cavity 141. Alternatively, the diameter of each of the through-hole may increase as a function of depth, as FIG. 1e illustrates with a wider part 151 at the bottom of the through-hole. It should be appreciated that these options can be combined with any other embodiment presented in this disclosure.

As described in more detail below, the plug may be created in the through-hole by depositing a plug material on the top surface (e.g., an outer surface facing away from the device layer) of the cap layer 13 so that this material enters the through-hole and gradually seals it. In practice, the plug material may be deposited on the sidewalls of the through-hole until the layer on the sidewalls becomes so thick that the plug which closes the entire through-hole is formed. The accumulation of plug material on the sidewalls will with some deposition methods be faster at the top of the through-hole than at the bottom.

FIG. 1f illustrates how such a plug may look in practice. Only the part of the plug 16 that closes the entire cross-section of the through-hole fulfils the sealing function, but the plug may nevertheless extend further downward along the sidewalls of the through-hole. The shape of the plug will depend on the deposition method. FIG. 1f also illustrates that some residual plug material 161 may be deposited on the area of device layer 12 which lies directly below the through-hole. It may therefore be preferable to select the location of the through-hole so it is not vertically aligned with the mobile microelectromechanical structures 121, or any other sensitive structures in the device layer, so that no extra material is deposited on these structures. As FIG. 1f illustrates, the cavity may for example be located in a region in the xy-plane which overlies a fixed part 122 of the device wafer. The residual plug material 161 is then instead deposited on the fixed part 122 and will not influence the mobile structure 121. The same effect can be achieved by giving the through-hole a meandering shape, but partly vertical and partly horizontal meanders with a narrow cross-section may be difficult to manufacture. The options illustrated in FIGS. 1a-1e can be combined with the options illustrated in FIG. 1f.

In any of the exemplary embodiments in this disclosure, the plug material may be an insulating material, for example, silicon dioxide. Alternatively, the plug may be a semiconductive material, for example polysilicon, or a metal such as aluminium. The cap layer may comprise one or more silicon regions, and the through-hole may be located in one of the silicon regions. The entire cap layer may form a single silicon region, or the cap layer may comprise silicon regions and also regions of some other material. In either case, the through-holes in the one or more silicon regions may be filled for example by growing silicon dioxide or polysilicon on the top surface of the cap layer and the sidewalls of the through-holes until the through-holes have been sealed. The plug material may then be removed from the top surface so that only the plug within the through-hole remains.

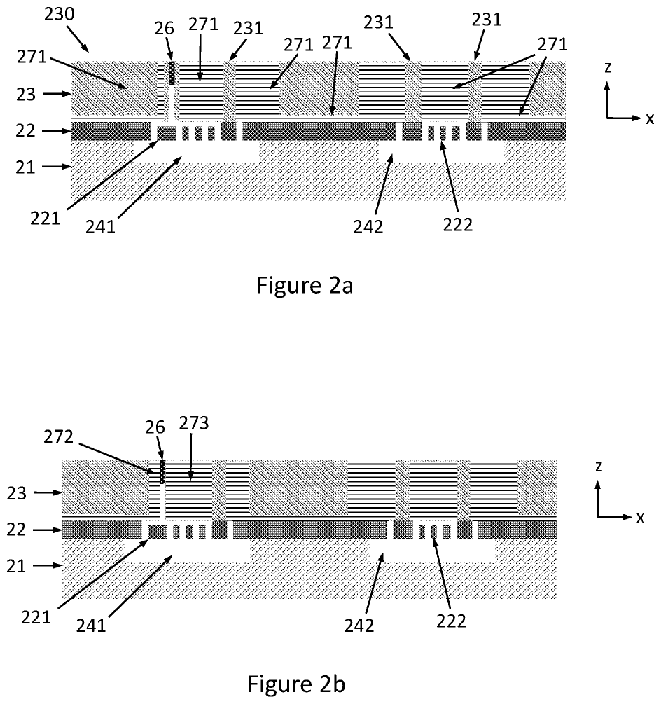

The cap layer may be made of silicon. It may be a silicon wafer. Optionally, the cap layer may comprise two or more silicon regions and one or more insulating regions which separate the two or more silicon regions electrically from each other. This configuration facilitates electrical contacting to the microelectromechanical structures from the top side of the cap layer. FIG. 2a illustrates a microelectromechanical component where reference numbers 21, 22, 23, 221, 222, 241, 242 and 26 correspond to reference numbers 11, 12, 13, 121, 122, 141, 142 and 16, respectively, in FIGS. 1a-1f.

In FIG. 2a, the cap layer comprises silicon regions 231 and insulating regions 271. The cap layer may include silicon regions and insulating regions, so that it does not comprise any additional regions. The insulating regions 271 may, for example, be made of glass or any other insulating material. The cap layer may then be a glass-silicon wafer, or a silicon-based wafer containing an insulating material. The insulating regions may have any suitable width in the xy-plane and any suitable thickness in the z-direction as long as they separate the silicon regions electrically from each other. The design illustrated in FIG. 2a can allow the microelectromechanical device structures to be electrically contacted to silicon regions 231 which extend to the top surface of the cap layer. External contacts, such as wire bonds, can then be attached to the silicon regions 231 on the top surface 230 of the cap layer to facilitate the desired measurements.

In FIG. 2a, the through-hole lies in one of the silicon regions and the sidewalls of the through-hole are silicon sidewalls. FIG. 2b illustrates an alternative option where the through-hole has been etched by entirely removing the silicon region which used to be between insulating regions 272 and 273. The sidewalls of the through-hole will in this case be made of the insulating material. In other words, the cap layer may comprise two or more silicon regions and one or more insulating regions which separate the two or more silicon regions electrically from each other. The through-hole may be located in one of the insulating regions.

It should be appreciated that the embodiments shown in FIGS. 2a and 2b can be combined with any other embodiment presented in this disclosure.

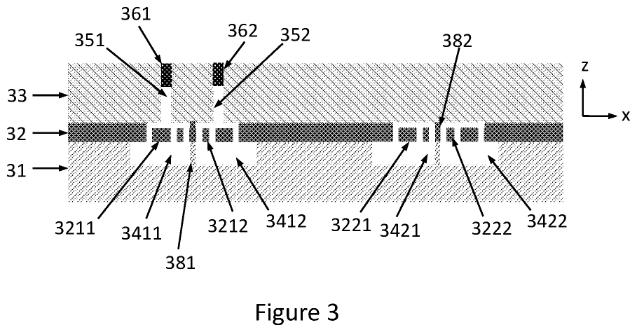

In some cases, the first cavity and/or the second cavity may be separated into two subcavities so that gas transfer is not possible between the subcavities. This option is illustrated in FIG. 3, where reference numbers 31, 32 and 33 correspond to reference numbers 11, 12 and 13, respectively, in FIGS. 1a-1f.

The microelectromechanical component may comprise at least one internal wall which divides the first cavity into two or more subcavities. The microelectromechanical component may comprise two or more through-holes so that one through-hole extends into each subcavity.

In the microelectromechanical component illustrated in FIG. 3, a first internal wall 381 extends in the vertical direction inside the first cavity and divides the first cavity into first and second subcavities 3411 and 3412. Correspondingly, a second internal wall 382 divides the second cavity into subcavities 3421 and 3422. The first and second internal walls may be manufactured by leaving certain areas in the support layer, the device layer and/or the cap layer unrecessed when adjacent areas are recessed. If these unrecessed areas are aligned with each other when the three layers are joined to each other, they can together form the internal walls 381 and 382 in the finished component. The first microelectromechanical device structure may correspondingly comprise a first part 3211 in first subcavity 3411 and a second part 3212 in second subcavity 3412. The second microelectromechanical device structure may comprise corresponding first and second parts 3221 and 3222. The first and second parts may together form a gyroscope/accelerometer element even though they are located in separate subcavities.

According to the exemplary aspect, no gas transfer occurs between these subcavities if the internal wall 381 divides the first cavity into two completely separated subcavities 3411 and 3412. To achieve the desired gas transfer in the subcavities before they are sealed with plugs, the component must in this case comprise one or more first through-holes 351 which extend to the first subcavity 3411 and one or more second through-holes 352 which extend to the second subcavity 3412. Each through-hole can then be sealed with a plug 361/362.

As mentioned before, in the finished component the pressure of the gas which fills the first cavity may be different from the pressure of the gas which fills the second cavity. The first cavity may, for example, be substantially at vacuum pressure, while the second cavity may be at atmospheric pressure, or vice versa. Alternatively or complementarily, the concentrations of different gas species may be different in the first and second cavities. It will typically be advantageous if the pressure and/or the gas species that is intended to fill the first cavity will also be well-suited for the deposition process which is used to deposit the plug material onto the cap layer. The options presented in this paragraph apply in any embodiments presented in this disclosure.

A method for manufacturing a microelectromechanical component will be described next. The component comprises a support layer, a device layer and a cap layer. The device layer is attached to the support layer. A first cavity and a second cavity are delimited by the support layer, the device layer and the cap layer. The method comprises: (1) forming recessed regions in the support layer, in the device layer and/or in the cap layer for delimiting the first and second cavities, (2) forming a through-hole through the cap layer, (3) attaching the cap layer to the device layer in a surrounding first gas atmosphere so that the through-hole overlies the first cavity, (4) changing the surrounding first gas atmosphere to a surrounding second gas atmosphere, (5) depositing a layer of plug material on the top surface of the cap layer at least over the through-hole until a plug which seals the through-hole has been formed inside the through-hole.

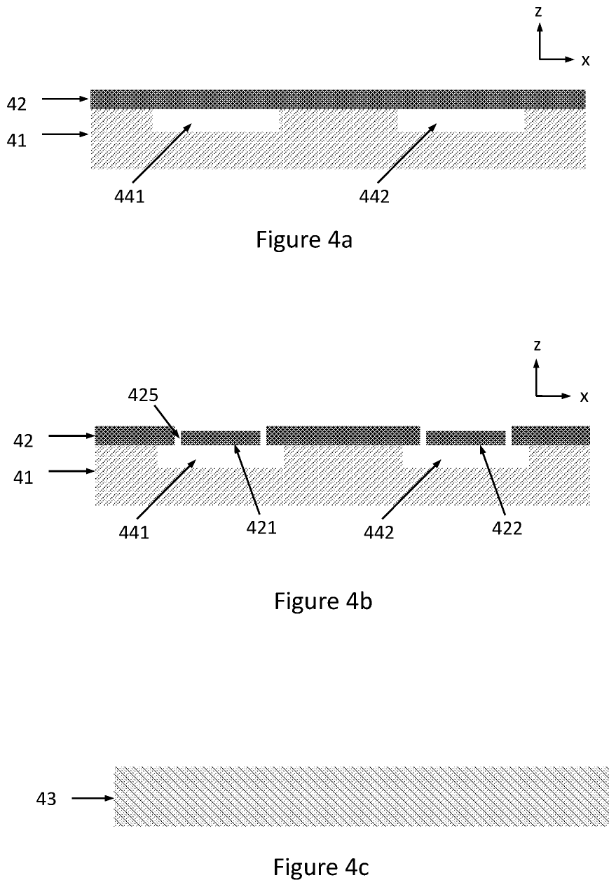

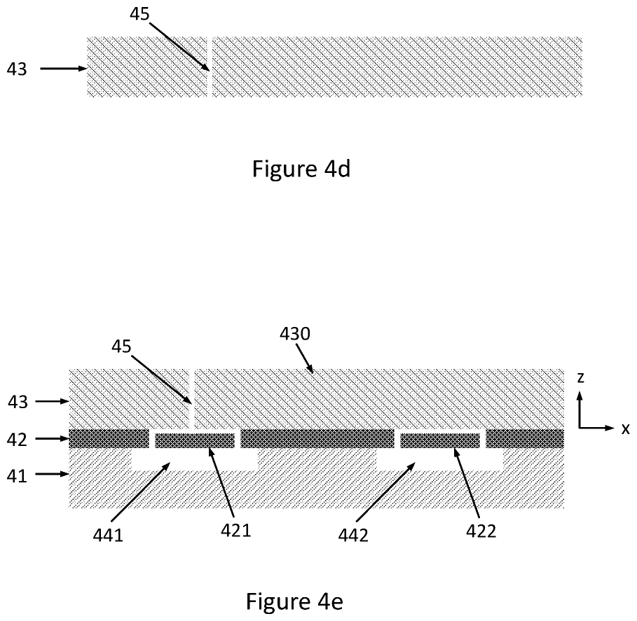

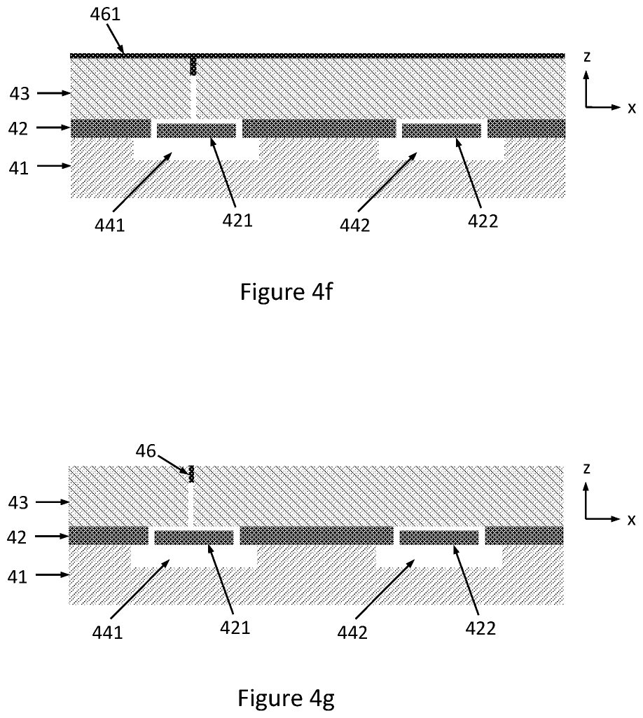

FIGS. 4a-4g illustrate one example of how the method may be implemented. Other implementations will also be indicated in the discussion below. Reference numbers 41, 42, 421, 422, 43, 441, 442, 45 and 46 correspond to reference numbers 11, 12, 121, 122, 13, 141, 142, 15 and 16, respectively, in FIG. 1a.

FIG. 4a illustrates the first part which is needed for this method. The support layer 41 and the device layer 42 may for example at the start of the method be a silicon-on-insulator (SOI) wafer where a thin device wafer has been attached to a thicker support wafer with an intervening insulating layer. In an exemplary aspect, the cavities 441 and 442 may have been formed in the support wafer 41 already before the device wafer was attached. Other alternatives are also possible. The cavities 441 and 442 may be formed in the support wafer by recessing the support wafer after the device wafer has been attached, or the cavities may be formed by recessing the device layer and cap layer and not recessing the support layer at all (as explained above). In the example illustrated in FIGS. 4a-4b, the support layer and the device layer are recessed.

Furthermore, the starting point does not necessarily have to be SOI wafer. The device layer could, for example, be made of a material that is gradually deposited on top of the support layer, and cavities may be prepared in the support layer after this attachment has been performed in an alternative aspect.

In the first method step in FIG. 4b, recessed regions have been formed in the device layer as FIG. 4b illustrates (the device layer has been recessed to make device structures 421 and 422 thinner in the z-direction). The device structures 421 and 422 may be partly released from the surrounding structures of the device layer in the same etching process where they are recessed. The device structures thereby become mobile, so that they can move in relation to the fixed regions of the device wafer.

FIG. 4c illustrates the cap layer 43 at the start of the method. The cap layer may be a wafer which can be bonded to the support wafer. A simple unitary layer is illustrated, but any of the more complicated layer structures described above may also be used. In the second method step shown in FIG. 4d, through-hole 45 is formed through the cap layer 43, for example, in a DRIE etching process. If necessary, some regions of the cap layer may also be recessed in an etching process to increase the size of the cavities 441 and 442. The recessing would then form a part of the first method step.

FIG. 4e illustrates the third method step where the cap layer 43 is attached to the device layer 42 so that the through-hole 45 overlies the first cavity 441. The cap layer 43 covers both cavities 441 and 442. If the cap layer is a wafer, the attachment may be performed in a wafer bonding process. It is significant that the gas which is enclosed in the second cavity 442 in FIG. 4e will be the gas where this attachment step is performed—the first gas atmosphere mentioned above. The second cavity 442 has now been sealed, so subsequent steps in the manufacturing process will not influence the content of this cavity.

In an alternative aspect, the second and third method steps could be performed in the opposite order. In other words, the cap layer 43 may not comprise any through-hole when it is attached to the device layer 42. The through-hole can instead be etched after the cap layer is attached to the device layer, but before the first gas atmosphere is changed into the second gas atmosphere in the fourth method step.

In the fourth method step (which is not illustrated in a separate figure), the surrounding first gas atmosphere is changed to a surrounding second gas atmosphere. The gas which was partly enclosed in the first cavity 441 in the third method step will now gradually be displaced by the gas of the second gas atmosphere. If the second gas atmosphere has a significantly lower gas pressure, for example a pressure close to vacuum, this replacement can be very quick. If the pressures of the two atmospheres are approximately equal but the gas species are different, the replacement may be slower. In any case, sooner or later the first cavity will be filled with the gas of the second gas atmosphere. When the through-hole 45 is sealed, the two cavities will contain gases with different pressures or different gas species.

FIG. 4f illustrates the fifth method step where a layer of plug material 461 is deposited on the top surface 430 of the cap layer 43 at least over the through-hole 45 until a plug which seals the through-hole 45 has been formed. If the plug material 461 is polysilicon, the deposition method may for example be CVD (Chemical Vapor Deposition) or LPCVD (Low Pressure Chemical Vapor Deposition). It should be appreciated that other deposition methods, such as sputtering or ALD may be used for other materials, but a key requirement for the deposition method is that it must be carried out in the second gas atmosphere.

FIG. 4g illustrates an optional sixth method step where the plug material 461 is removed from the top surface of the cap layer 43. This step can be performed for example by grinding or polishing the top surface. If the diameter of the through-hole 45 is on the order of a few micrometers and the deposition process was stopped soon after the through-hole had been completely sealed, then the vertical thickness of the layer of plug material 461 which should be removed may be as little as 5-10 micrometers. After the layer of plug material 461 has been removed, the plug 46 remains in the through-hole 45 and the top surface of the cap layer can be used for other purposes.

In general, it is noted that the exemplary embodiments described above are intended to facilitate the understanding of the present invention, and are not intended to limit the interpretation of the present invention. The present invention may be modified and/or improved without departing from the spirit and scope thereof, and equivalents thereof are also included in the present invention. That is, exemplary embodiments obtained by those skilled in the art applying design change as appropriate on the embodiments are also included in the scope of the present invention as long as the obtained embodiments have the features of the present invention. For example, each of the elements included in each of the embodiments, and arrangement, materials, conditions, shapes, sizes, and the like thereof are not limited to those exemplified above, and may be modified as appropriate. It is to be understood that the exemplary embodiments are merely illustrative, partial substitutions or combinations of the configurations described in the different embodiments are possible to be made, and configurations obtained by such substitutions or combinations are also included in the scope of the present invention as long as they have the features of the present invention.

What is claimed:

1. A microelectromechanical component comprising:
a support layer;
a device layer on the support layer; and
a cap layer having a top surface and that is on the device layer opposite to the support layer,
wherein the support layer, the device layer and the cap layer define a first cavity and a second cavity,
wherein the device layer includes a first microelectromechanical device structure in the first cavity and a second microelectromechanical device structure in the second cavity,
wherein the cap layer comprises a through-hole that extends from the top surface of the cap layer to the first cavity, and
wherein a plug is disposed inside the through-hole to seal the first cavity.

2. The microelectromechanical component according to claim 1, wherein the cap layer comprises one or more silicon regions, and the through-hole is in one of the one or more silicon regions.

3. The microelectromechanical component according to claim 2, wherein the cap layer comprises two or more silicon regions and one or more insulating regions that separate the two or more silicon regions electrically from each other.

4. The microelectromechanical component according to claim 1, wherein the cap layer comprises two or more silicon regions and one or more insulating regions that separate the two or more silicon regions electrically from each other, and the through-hole is in one of the insulating regions.

5. The microelectromechanical component according to claim 1, further comprising at least one internal wall that divides the first cavity into two or more sub-cavities.

6. The microelectromechanical component according to claim 5, further comprising two or more through-holes that respective extend into each of the two or more sub-cavities, respectively.

7. The microelectromechanical component according to claim 1, wherein the width of the through-hole decreases as a function of depth.

8. A microelectromechanical component comprising:
a support layer that includes a first cavity and a second cavity disposed therein;
a device layer on the support layer and including a first microelectromechanical device structure in the first cavity and a second microelectromechanical device structure in the second cavity;
a cap layer on the device layer opposite to the support layer and including a through-hole that extends from an outer surface of the cap layer to the first cavity; and
a plug in the through-hole to seal the first cavity.

9. The microelectromechanical component according to claim 8, wherein the support layer, the device layer and the cap layer collectively define the first cavity and the second cavity.

10. The microelectromechanical component according to claim 8, wherein the cap layer comprises two or more silicon regions and one or more insulating regions that separate the two or more silicon regions electrically from each other.

11. The microelectromechanical component according to claim 10, wherein the through-hole is in one of the insulating regions.

12. The microelectromechanical component according to claim 8, further comprising at least one internal wall that divides the first cavity into two or more sub-cavities.

13. The microelectromechanical component according to claim 12, further comprising two or more through-holes that respective extend into each of the two or more sub-cavities, respectively.

14. A method for manufacturing a microelectromechanical component that includes a support layer, a device layer and a cap layer, the method comprising:
forming recessed regions in at least one of the support layer, the device layer and in the cap layer to define for delimiting a first cavity and a second cavity;
forming a through-hole through the cap layer;
attaching the cap layer to the device layer in a surrounding first gas atmosphere so that the through-hole overlies the first cavity;
changing the surrounding first gas atmosphere to a surrounding second gas atmosphere that is different than the surrounding first gas atmosphere; and
depositing a layer of plug material on the top surface of the cap layer at least over the through-hole until a plug that seals the through-hole is formed inside the through-hole.

15. The method according to claim 14, further comprising forming the cap layer to include one or more silicon regions, and forming the through-hole in one of the one or more silicon regions.

16. The method according to claim 15, wherein the plug material is polysilicon.

17. The method according to claim 14, further comprising forming the cap layer to include two or more silicon regions and one or more insulating regions that separate the two or more silicon regions electrically from each other.

18. The method according to claim 14, further comprising:
forming the cap layer to include two or more silicon regions and one or more insulating regions that separate the two or more silicon regions electrically from each other; and
forming the through-hole in one of the insulating regions.

19. The method according to claim 14, further comprising:
forming at least one internal wall that divides the first cavity into two or more sub-cavities; and
forming two or more through-holes, so that one through-hole extends into each of the two or more sub-cavities, respectively.

20. The method according to claim 14, further comprising forming the through-hole to have a diameter that decreases as a function of depth.
